(19) United States
(12) Patent Application Publication
(10) Pub. No.: US 2005/0224912 A1
(43) Pub. Date: Oct. 13, 2005

(54) Circuit and method for enhanced low frequency switching noise suppression in multilayer printed circuit boards using a chip capacitor lattice

(76) Inventors: Shawn D. Rogers, Jessup, MD (US); William E. McKinzie III, Fulton, MD (US)

Correspondence Address: BRINKS HOFER GILSON & LIONE, P.O. BOX 10395, CHICAGO, IL, 60610, US

(21) Appl. No.: 10/802,664

(22) Filed: Mar. 17, 2004

(51) Int. Cl. H01L 29/00

(52) U.S. Cl. 257/532; 438/957

(57) ABSTRACT

A printed circuit board (PCB) uses arrays of chip capacitors over the entire surface of the PCB. The PCB includes an upper conductive surface routing signals to components of the PCB, a lower conductive surface, vias between the upper and lower surfaces, and a layer of patches disposed between the upper and lower surfaces to which the vias and chip capacitors are connected. The chip capacitors connect the vias to the upper conductive surface. The use of chip capacitors in a periodic lattice extends the frequency range for suppressing noise in power planes of isolated capacitors from several hundred MHz or less to 4 GHz. Combining the capacitors along with the buried patches extends the low frequency cutoff of high frequency reference noise suppression circuits to 50 MHz or less.

### BACKGROUND

This invention is related generally to reduction of noise induced in power planes due to switching of digital circuits in multilayer printed circuit boards. More particularly, the present invention is related to circuits and method for suppression of transverse electromagnetic modes in parallel plate waveguides.

A common problem in electronic systems is switching noise induced in the power distribution system by the operation of digital circuits in the system. Conventionally, such a system has one or more power planes designated, for example, +Vcc, and one or more ground planes. The potential difference between the power plane and the ground plane provides operating voltage for the circuits of the system. If the system includes digital or other circuits with fast-switching outputs, noise can be induced in the power planes and even in the ground plane. The noise may have several sources, but generally is due to the high slew rate of the digital output and the non-zero inductance of the power plane. Especially for an output driving a large capacitive load, the L(di/dt) noise can be substantial. This noise on the power plane can affect other circuits, slowing system operation or producing data errors. The problem occurs in all types of systems, including integrated circuits and circuits formed on printed circuit boards (PCBs).

One of the techniques to mitigate power plane noise induced by digital switching uses radio frequency (RF) bypass capacitors between +Vcc and ground layers. Other techniques use a very thin high dielectric constant material between the parallel-plate waveguides for power distribution or split power planes which meet at only one common point.

The use of board-mounted bypass capacitors is the standard noise suppression approach. The idea of this approach is to provide a very low reactance path between power and ground to decouple high-frequency signals (noise) from the power terminal of a switching device such as a digital IC. To this end, capacitors of widely different values (lower values have less parasitic inductance) are placed as close as possible to the power pins of integrated circuits. These capacitors are scattered and distributed only in a few locations where large integrated circuits such as the microprocessor exist.

Depending on the application, this approach may be adequate to reduce the power plane noise problem to an acceptable level. However, as the circuitry in electronics utilize higher frequencies, scattered capacitors will not be able to serve designs in the future.

The use of very thin (˜2 mil) dielectric cores, such as Nelco 4000-13 BC or ZBC 2000™ from Merix Corp., Forest Grove, Oreg., to separate power and ground planes helps to decouple RF signals so that the required number of decoupling capacitors may be reduced. This approach is called a buried capacitor layer. However, it will not suppress the parasitic resonance of parallel plate modes because it will not cut off transverse electromagnetic (TEM) modes.

Subdividing the power and/or ground planes into multiple smaller planes connected only at one point will help to isolate digital noise and raise the frequency of parasitic resonances, but it will not eliminate the power plane noise problem. There are also practical limits as to how small or narrow power or ground planes can be made. As the conductors become narrower, the self inductance of the traces can create noticeable voltage drops due to L(di/dt) when fast switching occurs for high current loads. Also, narrow necks in the power or ground planes can cause heating due to resistive losses or complete breakdown at sufficiently high current levels.

One reference (Kamgaing, 2002) has described a parallel plate waveguide which has a lower plate formed by an electromagnetic bandgap structure. While the disclosed device has some desirable features, the overall thickness of the disclosed parallel plate waveguide is more than 4.5 mm. For modern printed circuit board applications, this dimension is far too large for practical application. A much thinner parallel plate waveguide is required for integration as a power distribution system in a PCB.

In addition, it is desirable to have as wide a stopband as possible. The stopband is the range or band of frequencies over which noise and electromagnetic coupling are suppressed or attenuated. It is also desirable to have the lower edge of the lowest stopband attenuate signals at low frequencies (below a few hundred MHz or less).

Accordingly, there is a need for improved circuits, devices and methods for reducing induced power plane noise and improving electrical isolation between the various chips sharing a power distribution network (PDN).

### BRIEF SUMMARY

By way of introduction only, the present embodiments provide a two-dimensional, periodic, metallo-dielectric structure, which acts as a distributed microwave bandstop filter integrated into a parallel-plate waveguide. These embodiments can be used as an electromagnetic interference (EMI) filter to suppress digital noise on power planes, as well as to eliminate power plane resonances. Hence, they may be used for EMI and EMC (electromagnetic compatibility) purposes in printed circuit boards. The periodic structures disclosed herein have electromagnetic stopbands and passbands for TEM-like modes that propagate in parallel-plate waveguides. Therefore, these structures share characteristics of electromagnetic bandgap (EBG) filter concepts. The embodiments described herein extend the lower edge of the fundamental (i.e. lowest frequency) stopband of similar reference structures to well below several hundred MHz.

In other disclosures, periodic structures containing buried patches capacitively coupled to an upper plane and connected to a lower plane through vias were shown to cut off noise over frequency bands at which decoupling capacitors fail. Example designs implemented with printed circuit board (PCB) technology were shown to have a lower frequency cutoff of 1 to 2 GHz and an upper frequency cutoff between 5 and 10 GHz. The lower frequency cutoff is limited by the capacitance of the parallel plates formed by the buried patch and the upper conducting plane. If a much greater value of capacitance were used, the lower cutoff frequency would be decreased without increasing the thickness of the overall structure. Alternatively, the lower stopband frequency could be reduced by increasing the inductance of the vias. However, this is not usually desirable since it leads to a smaller stopband bandwidth. Increasing the via inductance may be accomplished by decreasing the via diameter, which adds cost, or increasing the length of the via, which adds to the board thickness. Thus, the preferred way to decrease the lower cutoff frequency is to increase the capacitance within each unit cell in the periodic structure.

Although surface mount technology (SMT) capacitors are relatively inexpensive to add to a PCB design, several problems exist with the placement of only a few scattered capacitors around a chip. Isolated capacitors have practical high frequency limits of about 1 GHz or less due to the parasitic series inductance of vias used to connect the bypass capacitor between +Vcc and ground layers. Also, apart from the vias, the parasitic inductance inherent in the capacitors reduces the high frequency limit of operation.

In particular embodiments, a new structure may be formed as part of a PCB power distribution network to reduce noise coupled from digital switching circuits to power and ground planes of the PCB. With current PCB technology, only a limited amount of capacitance can be realized with parallel plates. For example, a square parallel plate capacitor with sides of 250 mils that are separated by a dielectric material having a thickness of 2 mils and dielectric constant of 4.3 has a capacitance of 30 pF. Use of conventional SMT chip capacitors with much greater values of capacitance (e.g., 500 pF, 1800 pF, or more) that are connected with vias between the buried patches and the upper conducting plane increases the overall capacitance of the structure. The vias connecting the buried patches to the ground plane are actually extended toward the upper plane and are connected to the upper plane through the SMT capacitors. The addition of an SMT capacitor in substantially every cell of the structure enables the lower cutoff frequency of the fundamental stopband to be extended below 50 MHz.

In another embodiment, conductive vias are disposed between the upper and lower planes. An array of capacitors connects the vias on the upper layer to the conductive surface of the upper layer. On the lower layer, the same vias are directly connected to the conductive surface of the lower layer. In one example of this embodiment, the periodic arrays of capacitors of the same value without buried patches extend the high frequency cutoff of the same isolated capacitor. Three 1800 pF capacitors used in this experiment together have a measured self-resonant frequency of 125 MHz when connected to the power plane through vias of diameter 40 mils and length 30 mils and are not useful for decoupling above 200 MHz. These same capacitors when placed within a periodic array provide electromagnetic decoupling on the power planes to a maximum frequency of 4 GHz. Thus, the maximum frequency of decoupling has been extended by a factor of 20 simply by utilizing the inherent properties of the periodic lattice of capacitors.

By providing an array of capacitors and tailoring the characteristics of the capacitors in a regular or near regular lattice (i.e. periodic or nearly periodic structure), as well as the vias and any patches that may be present in the various structures, the structure may be optimized to produce a stopband in which TEM mode propagation is suppressed over desired frequency ranges including an enhanced low frequency stopband.

Adding an array of conventional SMT capacitors to a noise-mitigating structure containing an array of buried patches can extend the low-frequency cutoff from 1 to 2 GHz to 50 MHz or less. Therefore, cutoff may be realized from very low in frequency to 10 GHz using arrays of buried patches with arrays of SMT capacitors.

Thus, an isolated capacitor is useful for decoupling noise from power planes up to a maximum frequency of 100-500 MHz, depending upon the capacitance of the capacitor. An array of similar SMT capacitors even without buried patches extends the upper frequency cutoff of an isolated capacitor to much higher frequencies, such as 3 to 4 GHz in examples shown here. This example elucidates the power of lattice structures for exhibiting electromagnetic bandgap performance that is not evident from the individual components comprising the lattice. Thus, embodiments comprising arrays of buried patches and SMT capacitors offers significantly improved suppression of electromagnetic coupling and switching noise in power distribution networks over what has been attainable in conventional designs using isolated bypass capacitors alone or structures consisting of buried patches alone.

The foregoing summary has been provided only by way of introduction. Nothing in this section should be taken as a limitation on the following claims, which define the scope of the invention.

### BRIEF DESCRIPTION OF THE DRAWINGS

FIG. 1 is a cross-sectional view of a first embodiment of a parallel plate waveguide with buried patches and SMT capacitors;

FIG. 2 is a top view of an embodiment of the parallel plate waveguide illustrating the lattice of SMT capacitors;

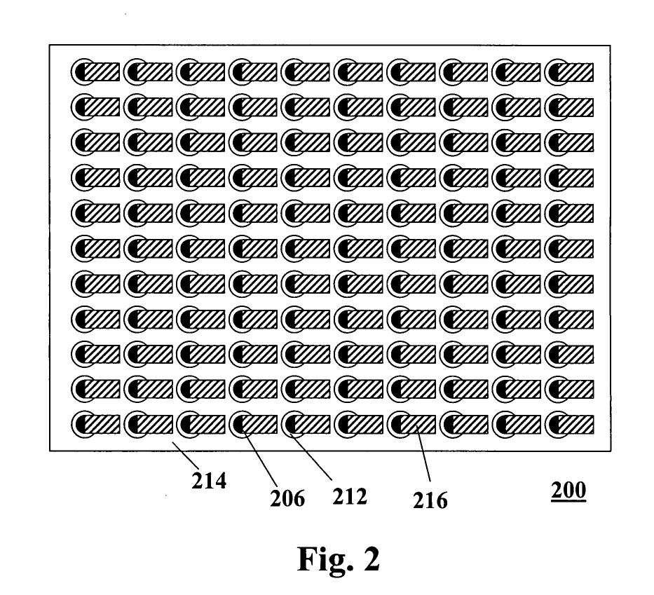

FIG. 3 is a cross-sectional view of the structure of FIG. 1 embedded within a PCB with signal layers on the top and bottom.

FIG. 4 is a top view of the embodiment of FIG. 3.

FIG. 5 is a cross-sectional view of the structure of FIG. 1 with the buried patches removed.

FIG. 6 is a cross-sectional view of the structure of FIG. 5 embedded within a PCB with signal layers on the top and bottom.

FIG. 7 is a cross-sectional view of an embodiment of the parallel plate waveguide having a lattice of SMT capacitors connected with plated through holes.

FIG. 8 is the structure of FIG. 7 with SMT capacitors mounted on the top and bottom of the PCB frequency.

FIG. 9 shows a transmission line equivalent circuit model of a unit cell of the embodiment of FIG. 1;

FIG. 10 shows a transmission line equivalent circuit model of a unit cell of the embodiment of FIG. 5;

FIG. 11 is a graph of the attenuation per unit cell for the embodiment of FIG. 1 calculated from a periodic wave propagation model;

FIG. 12 is a graph of the attenuation per unit cell for the embodiment of FIG. 5 calculated from a periodic wave propagation model;

FIG. 13 shows the calculated coupling between probes separated by 10 cells of the embodiment of FIG. 1 using the equivalent circuit of FIG. 9 for each cell;

FIG. 14 shows the calculated coupling between probes separated by 10 cells of the embodiment of FIG. 5 using the equivalent circuit of FIG. 10 for each cell;

FIG. 15 shows the top view of the hardware implementation of FIG. 2 with three ports labeled as illustrated.

FIG. 16 shows the bottom view of FIG. 15 with SMA connectors at the port locations.

FIG. 17 is a cross sectional view of the PCB stackup of the hardware of FIGS. 15 and 16;

FIG. 18 is a cross sectional view of the PCB stackup of a baseline parallel plate waveguide structure;

FIG. 19 shows the measured coupling between ports in the hardware of FIG. 15 compared to a baseline parallel plate waveguide of FIG. 18;

FIG. 20 shows the measured coupling between ports having the same layout of FIG. 15 for the embodiment of FIG. 5 with SMT capacitors only compared to the baseline case over the frequency span 50 MHz to 1 GHz;

FIG. 21 shows the measured coupling between ports having the same layout of FIG. 15 for the embodiment of FIG. 5 with SMT capacitors only compared to the baseline case over the frequency span 50 MHz to 10 GHz;

FIG. 22 shows a comparison of measurements of the three cases: SMT capacitors only, buried patches only, and SMT capacitors combined with buried patches;

### DETAILED DESCRIPTION OF THE PRESENTLY PREFERRED EMBODIMENTS

Applications, such as those in U.S. patent application Ser. No. ______ filed, entitled “Circuit and Method For Suppression of Electromagnetic Coupling and Switching Noise in Multilayer Printed Circuit Boards,” (hereinafter referred to as reference [1]) which claims priority to Provisional U.S. Patent Application Ser. No. 60/477,152 filed Jun. 9, 2003, entitled “Circuit and Method For Suppression of Transverse Electromagnetic Modes,” and concurrently filed U.S. patent application Ser. No. ______ entitled “Circuit and Method for Broadband Switching Noise Suppression in Multilayer Printed Circuit Boards Using Localized Lattice Structures,” all of which are hereby incorporated herein in their entirety by this reference, have focused on two dimensional lattices of buried patches and SMT capacitors and combinations thereof. The term lattice and array are interchangeable throughout this disclosure. The various arrangements in these applications (containing differing patch and via characteristics) may be incorporated as desired into the arrangements shown in the present application.

Switching of electronic devices such as microprocessors present on a PCB introduces noise in the power distribution network. The noise introduced has a fundamental frequency and harmonics related to the switching frequencies of the electronic devices, the materials and geometries used in the design of the PCB structure and other factors. Preferably, the features of the TEM mode suppression circuit disclosed herein are chosen to suppress or limit this noise. More particularly, the fundamental stopband of the TEM mode suppression circuit should be designed to suppress propagation of the TEM modes at frequencies of interest, e.g. the switching frequencies of the electronic devices. In this manner, noise introduced at a noise source in the power distribution network on either the positive voltage node or the ground node is significantly attenuated at other digital devices or other components of the PCB.

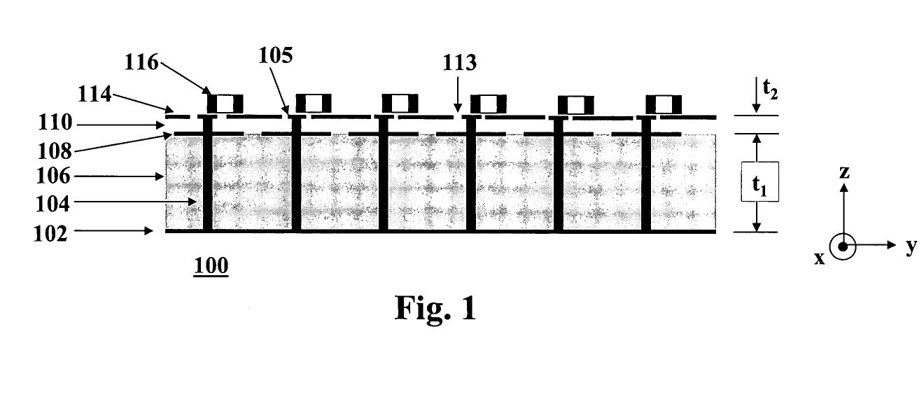

The embodiments described herein attenuate parallel-plate TEM modes that are naturally guided between the parallel conductive surfaces shown in FIG. 1. TEM modes are guided waves moving transverse or across the inside surface of the PPW, in parallel with the plane of the PPW. As shown in FIG. 1, the metal or other conductor planes lie parallel to the x-y plane. A TEM mode has a normal (z-directed) electric field and a transverse (x-directed) magnetic field, assuming wave propagation in the y direction. An empty parallel-plate waveguide (PPW) allows the TEM mode to propagate from DC to an infinite frequency. In this context, an empty PPW is one with no electromagnetic bandgap (EBG) structure. There exists no inherent cutoff frequency for TEM modes in an empty PPW.

The present embodiments create one or more stopbands of frequencies over which TEM modes do not propagate within a PPW. Hence these embodiments may be referred to as TEM mode suppression circuits. Frequency ranges in which the attenuation is substantially less than (30 dB or so) that in the stopband will be called passbands.

Referring now to the drawings, FIG. 1 illustrates a first embodiment of a parallel plate wave guide (PPW) 100 containing a transverse electromagnetic (TEM) mode suppression circuit. FIG. 1 is a cross-sectional view of the PPW 100. The PPW 100 includes a lower metal layer 102, an upper metal layer 114. Disposed a distance t₂ from the upper metal layer is a third metal layer 108 which forms buried patches. Metal layers 108 and 114 are separated by a dielectric layer 110 of thickness t₂. Metal layers 102 and 108 are separated by a dielectric layer 106 of thickness t₁. An array of conductive rods 104 of length t₁+t₂ and radius a extend between the lower layer 102 and the upper layer 114. Unless otherwise noted, the dimensions shown in the figures do not include the thickness of the conductive surfaces, which may be a relatively thin metal. The conductive rods may be solid metal poles or may be plated through holes (vias) whose edges are coated with metal but whose centers remain empty. The conductive layer 114 is a metal pattern that extends over substantially the entire top surface area of the upper layer, with openings for the conductive rods such that the only physical contact between the metal of the conductive rods and the metal of the conductive portion on the top surface of the upper layer is through the capacitors 116.

The period of the patches is generally the same as the period of the conductive rods and SMT capacitors, but may be different. Similarly, while the patches and capacitors usually exist in a one-to-one correspondence with each other such that each patch is associated with a capacitor, this is not necessary; particular areas of the board do not permit either patches or capacitors to be present. Although in general substantially the same number of the patches and capacitors are provided, quantification of the ratio is highly dependent on the design layout of the PCB. Similarly, although the lattice of capacitors generally are disposed over the entire surface area of the PCB/various layers, because the number and type of electronic components vary dependent on the board design and other requirements, absolute quantification of the overall coverage of the PCB by the lattice is likewise dependent. The patches 108 are much larger than the conductive rods 104. The patches 108 overlap with the conductive upper layer 114 to create parallel-plate capacitors in parallel with the capacitors 116.

The diameter of the conductive rod is, for example, 40 mils and the overall thickness of the PPW 100 is about 30 mils. Thus, FIG. 1 is not illustrated to scale. The conductive rods may, but are not required to, penetrate the entire height of the PCB structure. The thicknesses of the first dielectric layer 106 and second dielectric layer 110, for example, are 24 mils and 3 mils, respectively. The length of the conductive rods 104 in this example is the same as the total thickness of the PPW 100: 30 mils. The first dielectric layer 106 may be formed of any dielectric material such as RO5880 or FR4 with copper on both sides to form layers 102 and 108. Layer 108 is then etched using standard PCB processing techniques to create the buried patches. The upper dielectric layer 110 can be comprised of a thin FR4 or other dielectric material with copper on one side (114) and is attached to the lower dielectric 106 with a bonding film that is sometimes referred to as prepreg. Thus, the dielectric layer 110 may include both the laminate material (FR4) and the bonding film, both of which are dielectrics.

The combination of double clad and single clad dielectric sheet materials with prepreg bonding films comprise a specific stackup of a PCB design. Many combinations of stackups are possible to achieve a given cross section. The description of the stackup in FIG. 1 is exemplary only and does not limit the scope of the invention.

Sections 105 of the surface of the upper conductive layer 114 house ends of the conductive rods 104. More specifically, at the periphery of each conductive rod 104, a pad 105 is formed to terminate the conductive rod 104 on the upper surface of the PCB 100. To avoid a short circuit, a clearance space 113 is provided around the conductive pad 105 by etching or some similar means. The clearance space and the diameter of the pad in the embodiment shown in FIG. 1, for example, are preferably kept to a minimum to maximize the capacitance between the patches and the conductive surface of the upper layer.

Capacitors 116 (in one embodiment SMT capacitors such as 1800 pF, 50 VDC capacitors made by Panasonic, Digi-Key P/N PCC2157CT) connect the ends of the conductive rods 104 and pads 105 with the conductive upper layer 114. The capacitors 116 add additional capacitance to the structure, compared to structures containing only patches. The chip capacitors may also include non-SMT type capacitors.

The conductive rods 104 are oriented generally normal to both the lower layer 102 and the upper layer 114. Each respective conductive rod 104 is in electrical contact with the lower layer 102 and with a respective capacitor 116. In some embodiments, each plated through hole has an associated capacitor while in other embodiments, some of the capacitors or capacitors and conductive rods may be omitted so that there is not a one-to-one correspondence between conductive rods and capacitors.

The conductive rods 104 and capacitors 116 in the embodiment of FIG. 1 are arrayed in a square lattice of period d (for example, 250 mils). Various structures and reasons for using lattices are provided in U.S. Pat. Nos. 6,512,494 and 6,262,495 herein incorporated by reference in their entirety. In general, any two dimensional lattice consisting of arbitrary direction vectors and spacing may be used. The first and second dielectric layers 106, 110 form the host dielectric medium of the PPW 100. The first (lower) dielectric layer 106 of thickness t₁ has a relative dielectric constant of εᵣ₁, while the second (upper) dielectric layer 110 has a relative dielectric constant of ε₂. One example of materials used for the lower dielectric layer includes RO5880, which has a dielectric constant of 2.5. An example for the upper dielectric layer is FR4, which has a dielectric constant of 3.9. In order to maximize the stopband bandwidth, the relationships between these thickness and dielectric constants should be t₂<t₁ and εᵣ₂>εᵣ₁.

The dielectric layers 106, 110 are normally isotropic. However, as only the normal or z-directed tensor component of permittivity affects the electric field of the TEM mode, if anisotropic dielectric materials are used for the layers 106 and 110, then the z tensor element can be substituted for the relative dielectric constant.

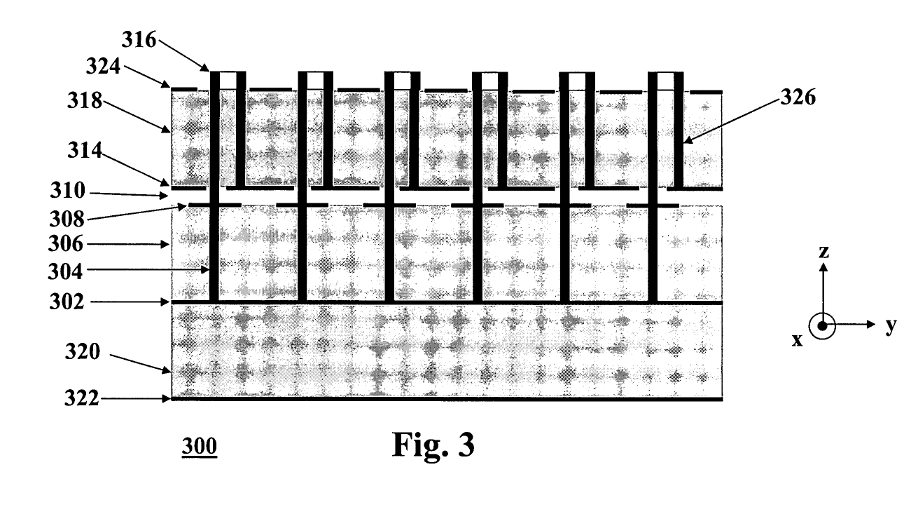

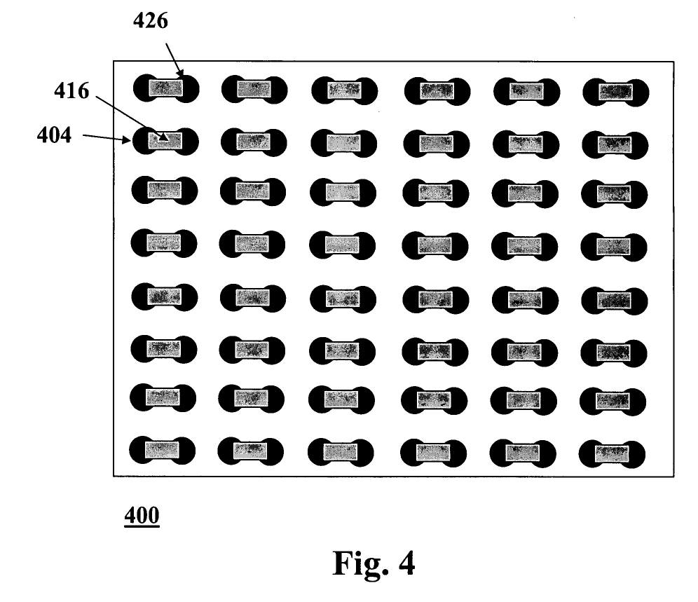

FIG. 3 illustrates a cross-section view of the noise suppression circuit of FIG. 1 embedded within a multilayer PCB. In this embodiment, dielectric layers 318 and 320 are added to the top and bottom of the parallel plate structure of FIG. 1. In this example, metal layers 324 and 322 are used to route signals to various chips on the board. Layer 314 is used as the Vcc plane, and layer 302 is used as the ground plane. The vias 304 connect the patches 308 and the capacitors 316 to the ground plane 302 through the dielectric layers 306, 310, 318. The vias 326 connected the capacitors 316 to the Vcc plane 314 through the dielectric layer 318. FIG. 4 illustrates a top view of this configuration showing that each lead of a given capacitor 416 is connected to vias 404, 426 which extend into the PCB 400.

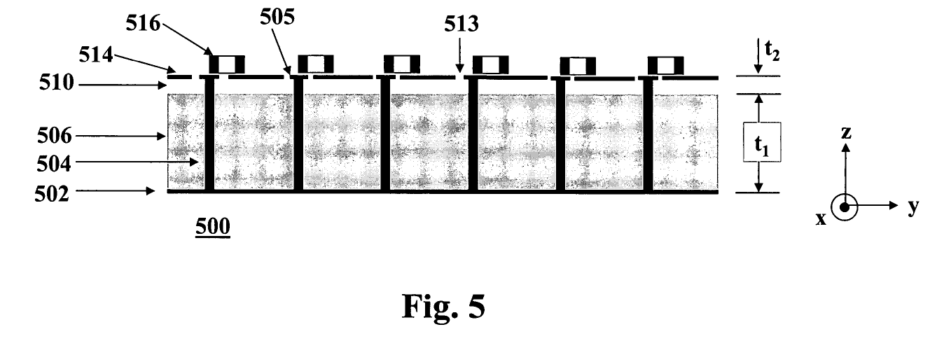

In some applications, the buried patches may be eliminated and the noise suppression circuit becomes a periodic lattice of SMT capacitors only, as illustrated in FIG. 5. This embodiment is the same as that of FIG. 1 with the buried patches removed. The vias 504 connect the capacitors 516 to the ground plane 502 through the dielectric layers 506, 510. Pad 505 is again separated from the metal layer 514 by a clearance space 513.

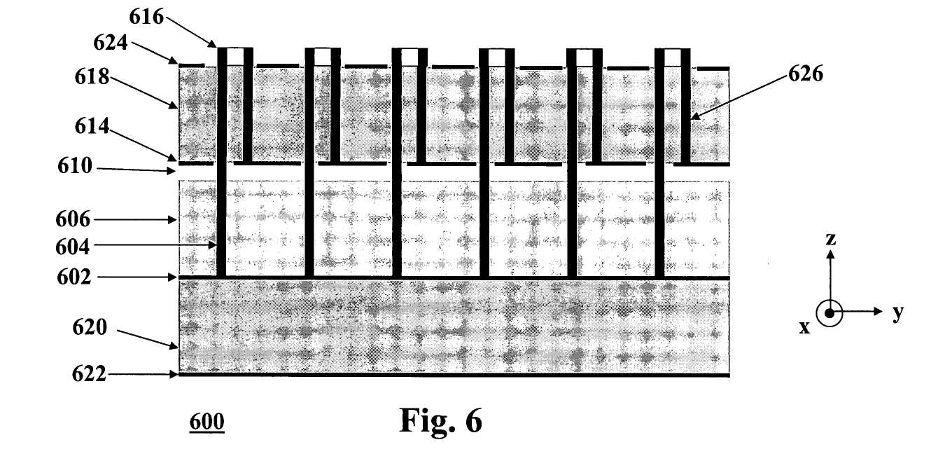

FIG. 6 shows the embodiment used within a multilayer printed circuit board 600. In this example, vias 604 and 626 connect the SMT capacitors to the ground plane 602 and Vcc plane 614, respectively. In this embodiment, dielectric layers 618 and 620 are added to the top and bottom of the parallel plate structure of FIG. 1. In this example, metal layers 624 and 622 are used to route signals to various chips on the board. The vias 604 connect the capacitors 616 to the ground plane 602 through the dielectric layers 606, 610, 618. The vias 626 connected the capacitors 616 to the Vcc plane 614 through the dielectric layer 618.

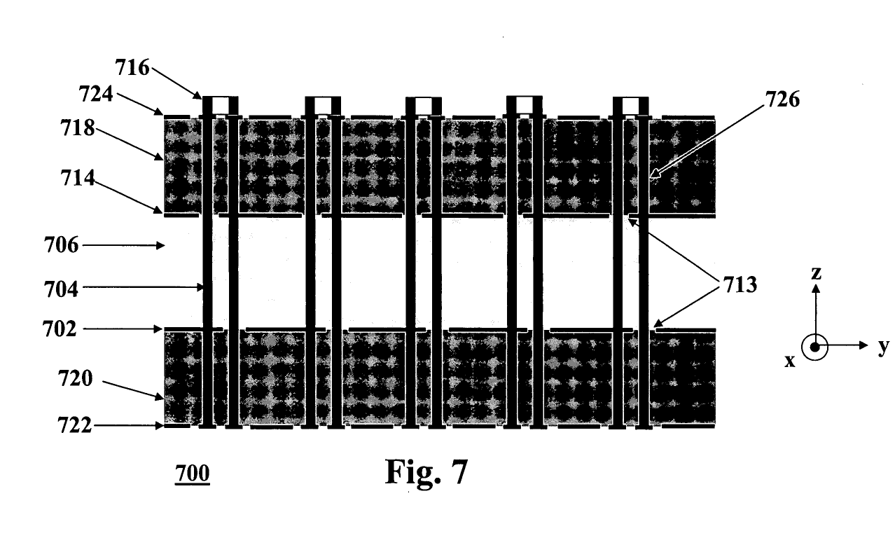

FIG. 7 shows an example of the periodic lattice of SMT capacitors in which plated through holes penetrate the PCB 700 and connect to the Vcc plane 714 and ground plane 702. In this example, only one dielectric layer 706 is used to separate the Vcc plane 714 and ground plane 702 since there are no buried patches. The signal layers 722, 724 contain traces that carry digital transmissions between various chips and also make connections to discrete components. The vias 704 connect the capacitors 716 to the ground plane 702 through the dielectric layers 706, 718 and extend to ground traces on the bottom signal layer 722 through the dielectric layer 720. Similarly, the vias 726 connected the capacitors 716 to the Vcc plane 714 through the dielectric layer 718 and extend to ground traces on the bottom signal layer 722 through the dielectric layers 706, 720. As in the other embodiments, clearance spaces 713 are formed between the vias and the metal of the other layers through which they pass (e.g. Vcc plane 714 for via 704 and ground plane 702 for via 726).

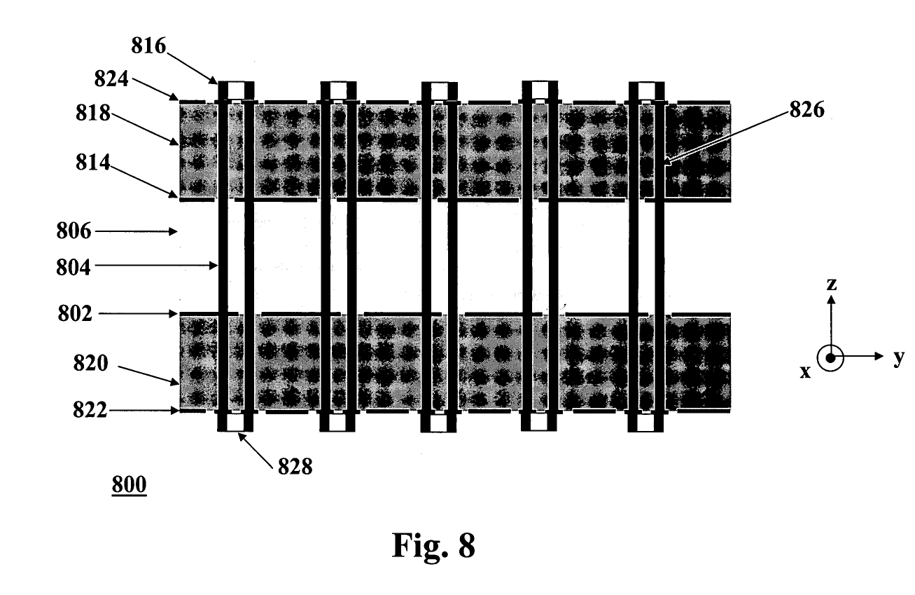

In the embodiment of FIG. 8, SMT capacitors 816 and 828 are located on both sides of the PCB 800 and are connected to the Vcc plane 814 and the ground plane 802 through vias 804 and 826. Again, only one dielectric layer 806 is used to separate the Vcc plane 814 and ground plane 802 since there are no buried patches. The signal layers 822, 824 contain traces that carry digital transmissions between various chips and also make connections to discrete components in addition to the capacitors 828. Dielectric layer 820 separates the ground plane 802 from signal layer 822, while dielectric layer 818 separates the Vcc plane 814 from signal layer 824. This configuration yields more capacitance per unit cell than those having a capacitor on only one side of the board. Alternatively, the embodiment 800 allows greater flexibility in the PCB layout since capacitors may be removed on one side of the board in order to make room for chips while still remaining on the opposite side of the board for improved noise suppression.

Of course, in any of the above embodiments, geometries other than square lattices may be used to create the array (e.g. hexagonal or triangular lattices) so long as waves of electromagnetic energy at the desired frequencies are attenuated between the points of interest.

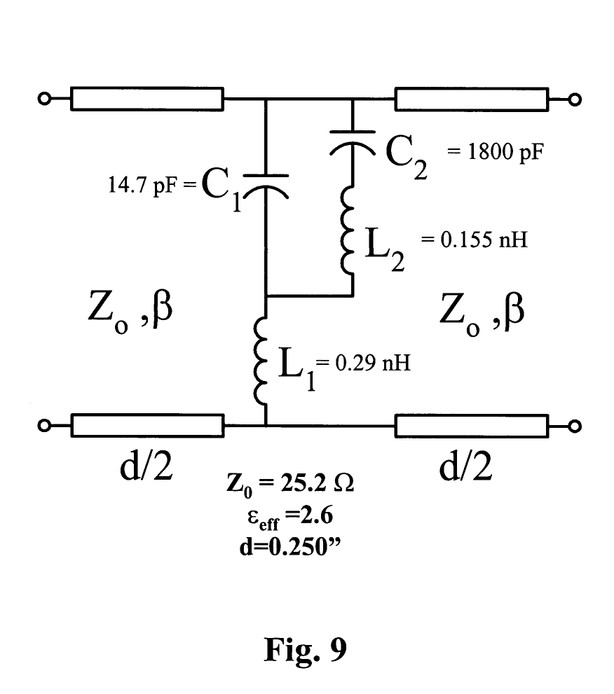

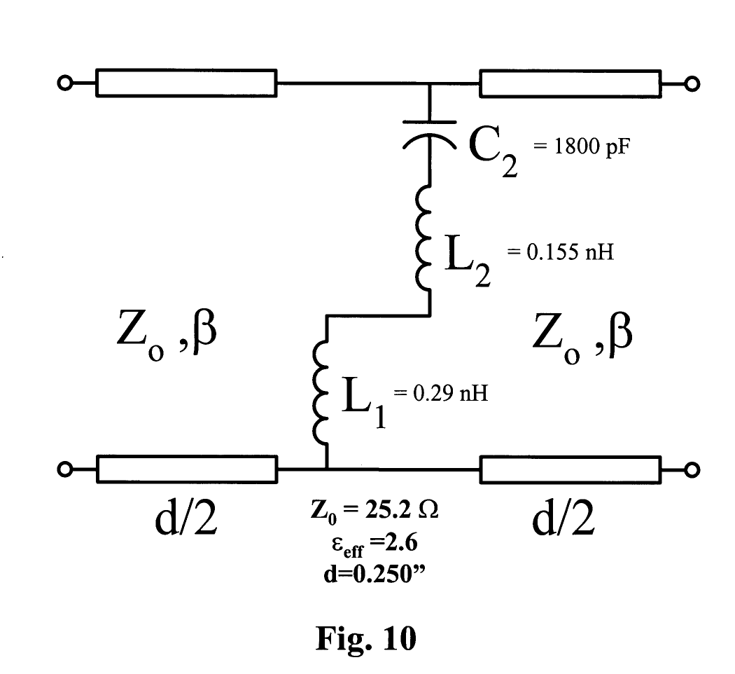

FIG. 9 illustrates a transmission line circuit model of one unit cell of the low frequency enhanced noise suppression circuit of FIG. 1. In this circuit model, the capacitance C1 is the parallel plate capacitance formed by the buried patches 108 and the upper conducting plane 114. L1 is the inductance of section of the via 104 that extends from the ground plane 102 to the buried patch 108. L2 is the inductance of the section of the via 104 that extends from the buried patch 108 to the upper conducting plane 114. C2 is the capacitance of the SMT capacitor that is connected between the via pad 105 and the upper conducting plane 114. FIG. 10 illustrates a transmission line circuit model of one unit cell of the low frequency enhanced noise suppression circuit of FIG. 5. In this model, the capacitance of the buried patch C1 is removed. The remaining circuit elements used to create the stopband are L1 and L2 which together represent the inductance of the vias 504 and C2 which is the capacitance of the SMT chip capacitor. It is recognized that this circuit model for the unit cell is the same as the one described in reference [1]. However, in this case, the value of capacitance is much larger since SMT chip capacitors are used. Later, it will be shown that this leads to significant improvement at frequencies below 1 GHz. These circuit models of one unit cell can be used to predict the electrical performance of the low frequency enhanced noise suppression embodiments. Component values shown in FIGS. 9 and 10 are exemplary only and depend upon specific design requirements as described later.

The equivalent circuits in FIGS. 9 and 10 are referred to as transmission line equivalent circuits (TLEC) and can be used in two ways. First, as described in detail in reference [1], analysis of an infinite periodic structure of identical TLECs will result in an ωβ diagram or dispersion diagram. Also, this method is used to generate plots of attenuation per unit cell. Second, a more convenient use of the TLEC is to chain a finite number of these cells together and analyze the resulting finite structure with a commercially available circuit simulator (such as Eagleware's Genesys). This second approach results in plots of S12 versus frequency.

Both cases of the low-frequency enhanced structures of FIG. 1 and FIG. 5 were modeled with the methods discussed above and were later fabricated and tested. The various circuit elements describing the unit cells in FIGS. 9 and 10 may be calculated from the geometry of the structure. In the unit cell of FIGS. 1 and 3, the patches are squares having a 230-mil side length (s) and a 20-mil spacing (g) between the patches. Thus, the period (d) of the array of patches is 250 mils. The first dielectric layer (t₁) is 24 mils thick and-has a relative dielectric constant (εᵣ₁) of 2.5, the second dielectric layer (t₂) is 3 mils thick and has a relative dielectric constant (εᵣ₂) of 3.8, each conductive rod has a radius a of 20 mils, and the capacitance (C₂) of each chip capacitor is 1800 pF. The capacitance (C₁) of the buried patches is calculated from the parallel plate capacitance formula (C₁=εᵣ₁ε₀s²t₂) to be around 14.7 pF. The inductance of each conductive rod from the lower layer to the layer of patches (L₁) is 0.29 nH, while the inductance from the layer of patches to the chip capacitor (L₂) is 0.155 nH. Expressions for calculating the inductance per unit length of a single rod embedded within a periodic structure of rods having period d is discussed in reference [1]. These expressions were used as a guide for determining the values of L₁ and L₂. The values used for L₁ and L₂ were varied so that the calculated results would more closely match the measured results presented later. The impedances (Z₀) of the transmission line sections are calculated to be 25.2 Ω while the effective dielectric constant (εᵣ₁×t₁+εᵣ₂×t₂)/(t₁+t₂) is 2.6. These transmission line sections are of half the length of the period d.

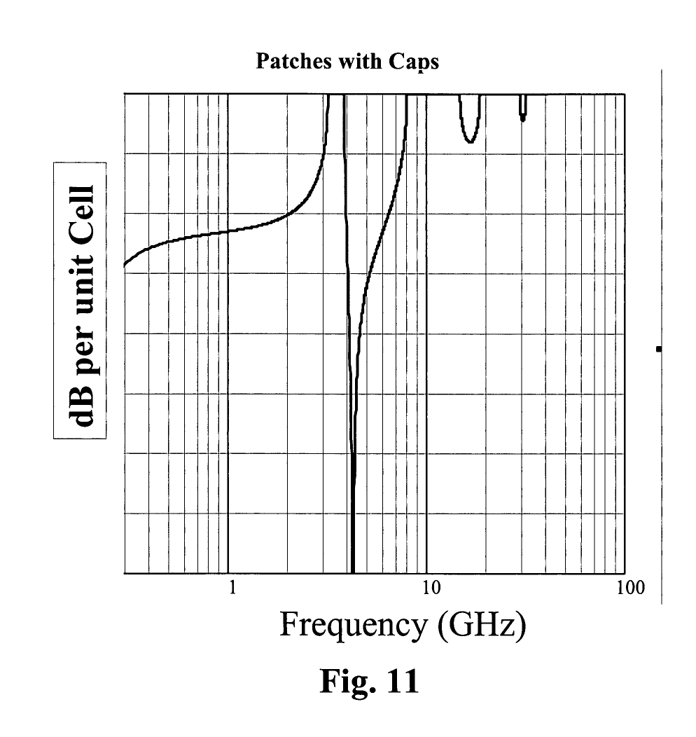

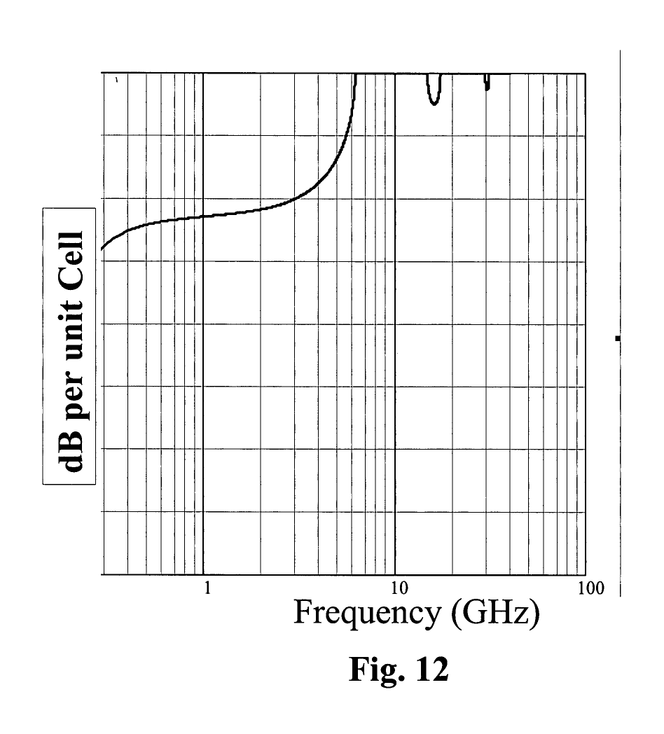

FIG. 11 shows the attenuation per unit cell for the TLEC illustrated in FIG. 9. This prediction illustrates that the first fundamental stopband exists over the frequency range 130 MHz to 3 GHz. A second stopband is predicted to occur over 4-8 GHz, and a narrow passband is predicted to exist over 3-4 GHz. When the capacitor C1 is removed from the TLEC in FIG. 9 resulting in the circuit model of FIG. 10, then the predicted frequency response is as illustrated in FIG. 12. This calculated result for the structure having SMT capacitors without buried patches shows a stopband over the frequency range 130 MHz-6 GHz.

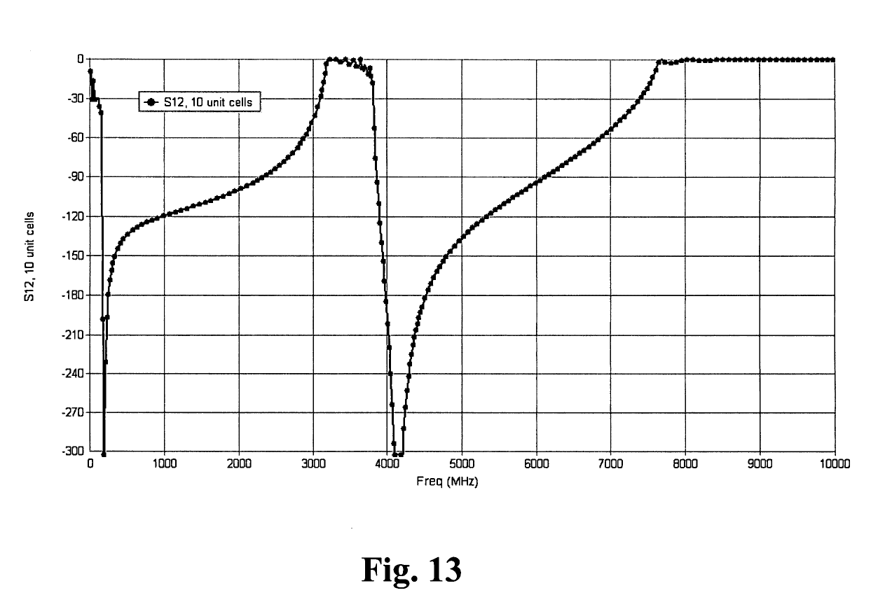

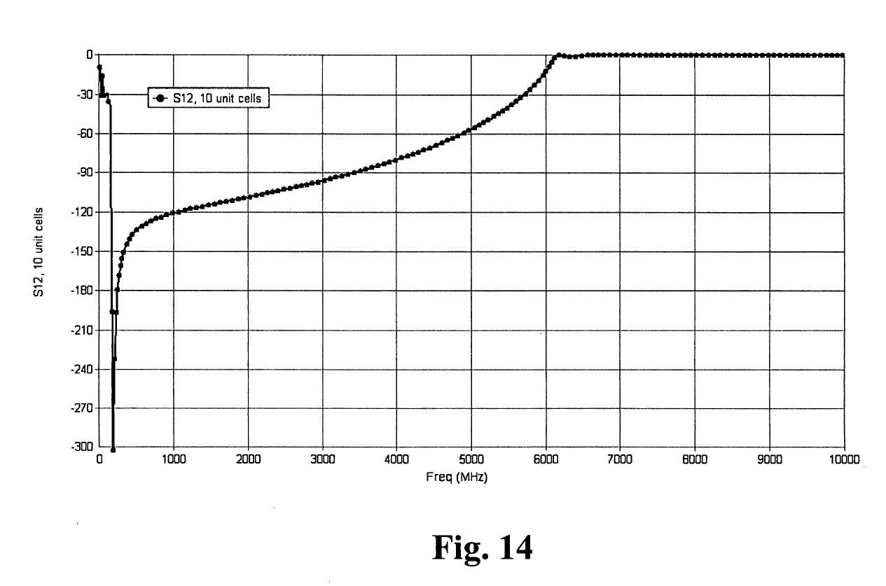

FIG. 13 is the calculated coupling data of two 50 Ohm ports with ten unit cells of FIG. 9 cascaded between them. This data indicates that a passband occurs between 3 and 4 GHz and stopbands occur between 150 MHz-3 GHz and 4 GHz-7.5 GHz. These results are very similar to the attenuation per unit cell data of FIG. 11. When the capacitance of the buried patches is removed from the circuit model, the coupling data of FIG. 14 is predicted. In this case, the stopband of 150 MHz-5.5 GHz is in good agreement with the calculated stopband in FIG. 12.

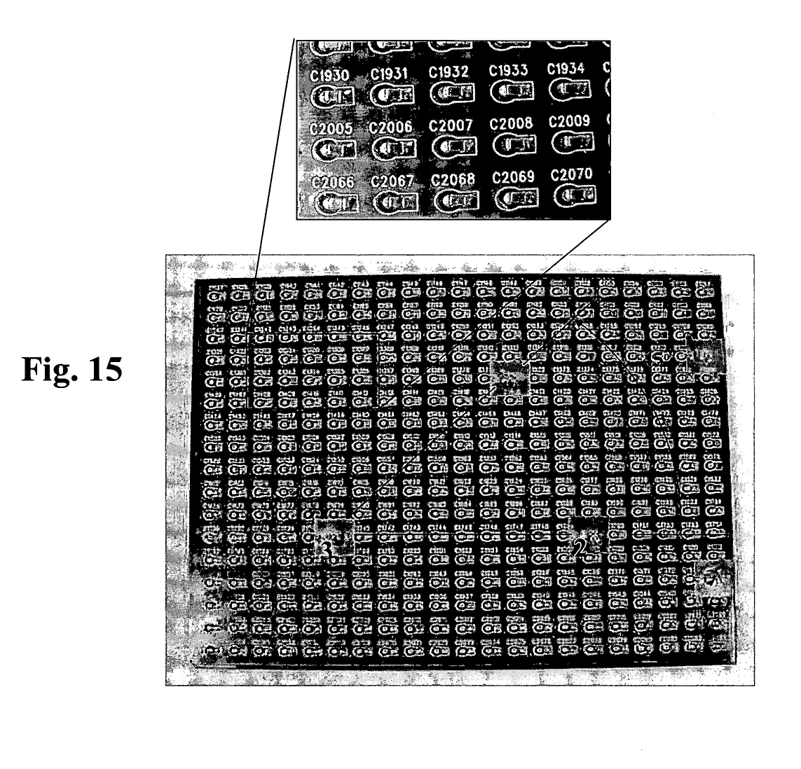

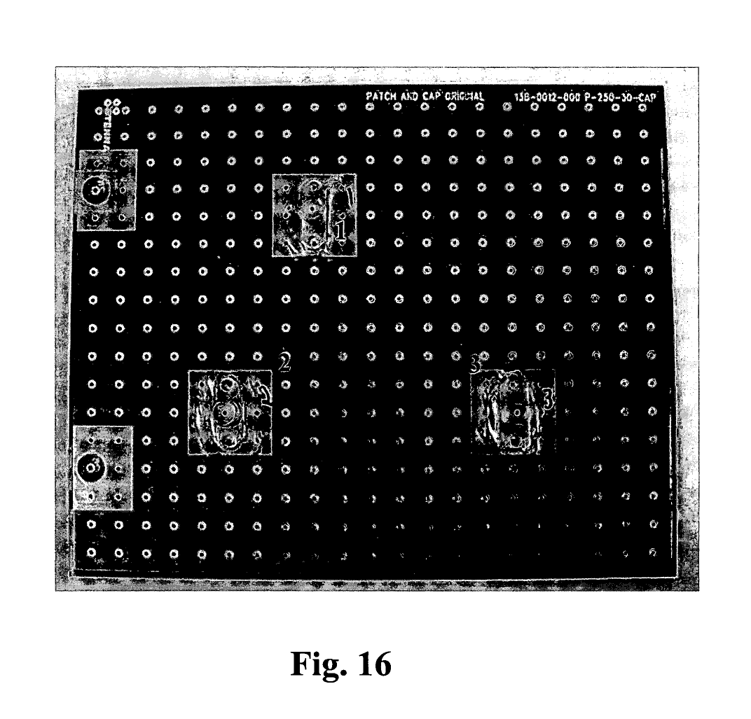

Hardware was fabricated in order to test the performance of the embodiments described in FIGS. 1 and 5. The top view of the hardware is shown in FIG. 15 and is representative of both embodiments with and without buried patches since the inside metal layer forming the patches cannot be viewed. SMT capacitors are soldered within each unit cell as described previously and are shown in the inset of FIG. 15. Three SMA connectors were soldered to the PCB and centered on drilled-out vias as shown in FIGS. 15-16. The center conductor for each connector was soldered to the upper conductive surface of the PPW and the outer conductor was soldered to the lower conductive surface of the PPW so as to excite or receive TEM modes. The PCBs contained 17×21 cells (4.25 inches×5.25 inches). As can be seen in FIG. 16, only the SMA connectors (i.e. no chip capacitors) were installed on the base of the PCB by soldering. The second and third SMA connectors were disposed along a horizontal line with 10 unit cells between them, while the first and third SMA connectors were disposed along a line 45° from the horizontal line with 7 unit cells (with or without patches or SMT capacitors) between them. The connectors were located in these positions in order to test the effects of coupling paths that are not aligned with the axes of the lattice structure. Each connector was located at least 4 unit cells from the nearest edge. Again, the materials and geometries are exemplary only.

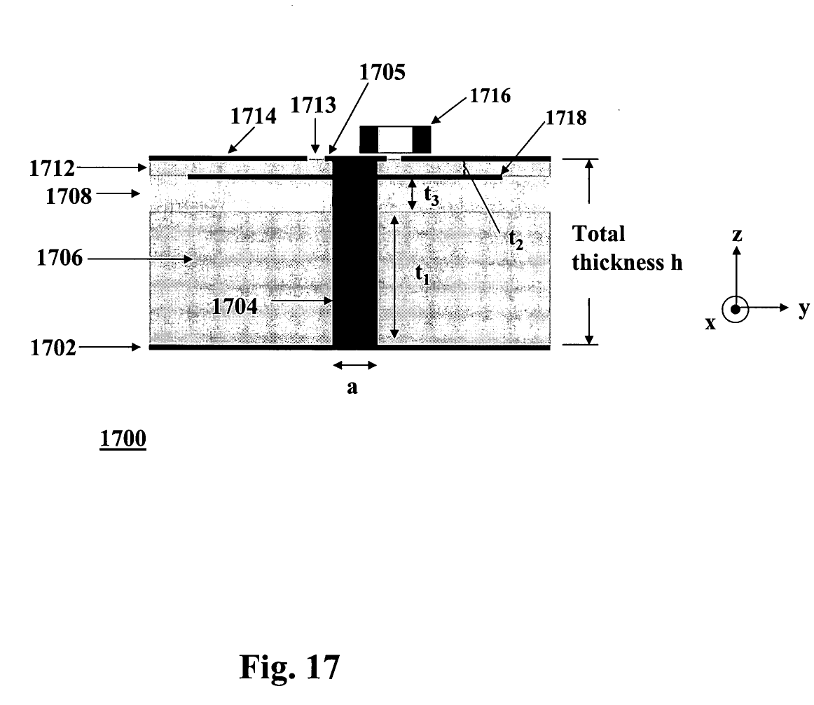

The PCB stackup for implementing the embodiment of FIG. 1 in hardware is shown in detail in FIG. 17. The PCB 1700 contains a first dielectric region 1706 made of RO5880 material which is a Teflon-based dielectric manufactured by Rogers Corporation, One Technology Drive, Rogers, Conn. 06263-0188. This dielectric material is 20 mils in thickness (t₁) and is clad with copper only on the bottom side to form the lower conducting plane 1702. A second dielectric material 1712 is 3-mil thick (t₂) FR4 with copper on both sides that forms the upper conducting plane 1714 and the buried patch layer 1718. After the copper of the second dielectric layer 1712 is etched on both sides with the appropriate artwork pattern, the two dielectrics 1706, 1712 are joined with a bonding material 1708 that is also referred to as prepreg which is 4 mils in thickness (t₃). The prepreg material is an epoxy loaded with woven glass fiber. The resulting stackup is pressed together under heat and pressure so that the prepreg 1708 will bond the two laminate layers together. The finished PCB 1700 has a total thickness of 30 mils. The structure 1700 is drilled and plated to form the conducting via 1704 that connects a pad 1705 on the upper surface to the buried patch 1718 and ground plane 1702. The pad 1705 is separated from the remainder of the upper conducting plane 1714 by a clearance space 1713. The diameter of the vias 1704 is 40 mils. In this case, 1800 pF SMT capacitors 1716 are soldered between the via pad 1705 and the upper conducting plane 1714. For the case in which no buried patches are present, the upper dielectric material 1712 has copper on only one side for the upper conducting plane 1714 and the other copper layer 1718 is completely removed.

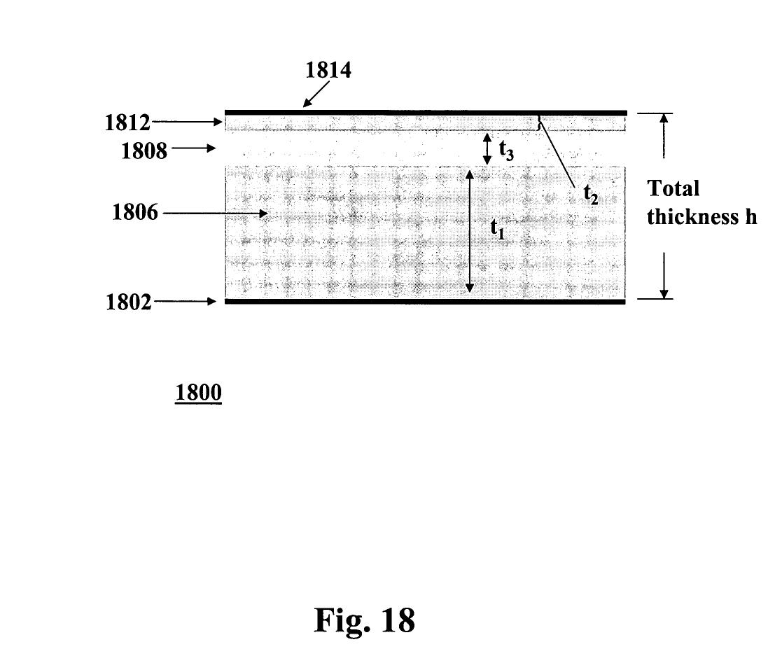

In order to demonstrate the improvement that is achieved when the noise suppression circuits are used, a baseline PPW was fabricated according to the stackup of FIG. 18. Essentially this is the same stackup as FIG. 17 with the buried patches, SMT capacitors, and vias removed. The stackup 1800 includes a bottom dielectric layer 1806 of RO5880 that has one layer of copper 1802 and is 20 mils in thickness (t₁). The upper dielectric layer 1812 is made of 3-mil thick (t₂) FR₄ and has copper only on the upper surface 1814. A bonding layer of prepreg material 1808 is of thickness 4 mils (t₃) and is used to adhere the two laminate regions together. Three coaxial connectors (not shown in FIG. 18) are soldered to the baseline board in the same locations as described previously for the other cases.

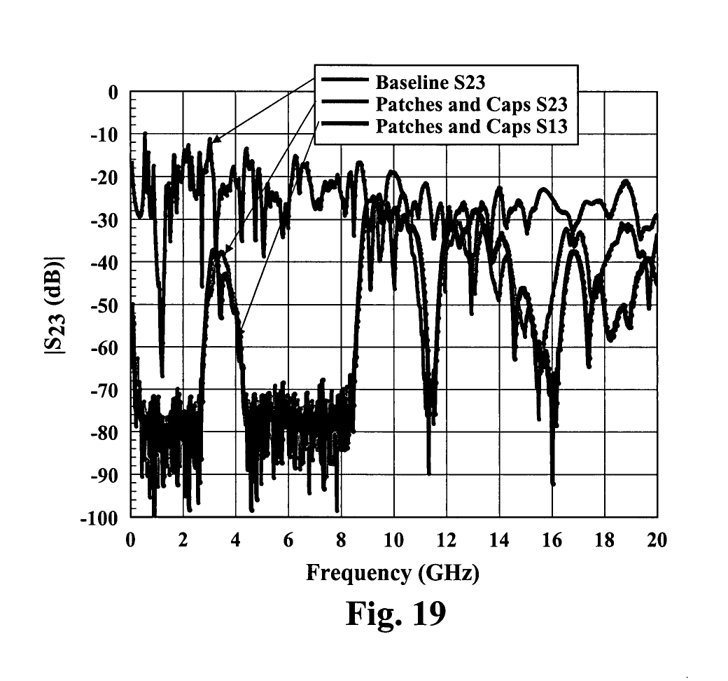

FIG. 19 is a graph of the measured transmission data of the hardware described in FIGS. 15-18. The coupling data for the baseline PPW is provided along with data for the noise suppression circuit embodiment having both SMT capacitors and buried patches. The measurements were performed on an HP8720ES vector network analyzer. The experiment was configured to determine if the coupling of power between the ports depends upon their alignment with the lattice of the periodic structure. In FIG. 15 it is seen that the line between ports 2 and 3 is aligned with an axis of the lattice, whereas the line between ports 3 and 1 is at a 45 degree angle to this axis. Ports 2 and 3 are separated by 9 unit cells and a distance of 2.5 inches. Ports 1 and 3 are separated by 6 unit cells and 2.5 inches. S13 is the ratio of power transmitted to port 1 and power incident from port 3 expressed in decibels. S23 is the ratio of power transmitted to port 2 and power incident from port 3. As is evident in the data of FIG. 19, despite the differences in the alignment of the ports, the transmission characteristics are very nearly the same between the third and second ports (S23) and between the third and first ports (S13). Thus, it is not necessary for the shortest coupling path between interferers on a printed circuit board to align with the lattice axis in order to get the benefit of noise suppression.

In FIG. 19, it is seen that the noise suppression circuit containing SMT capacitors along with buried patches attenuates coupling by an extremely large amount, 70 dB or more, over most of the frequency range between 50 MHz and 8.5 GHz. There is less attenuation, about 36 dB, occurring in the 3-4 GHz range. However, the attenuation of coupling over 3-4 GHz is still significant since it is about 20 dB better than the nominal response for the baseline case without a noise suppression circuit. Thus, the effective stopband is essentially from 50 MHz to 8.5 GHz in this example of a noise suppression circuit containing SMT capacitors and buried patches.

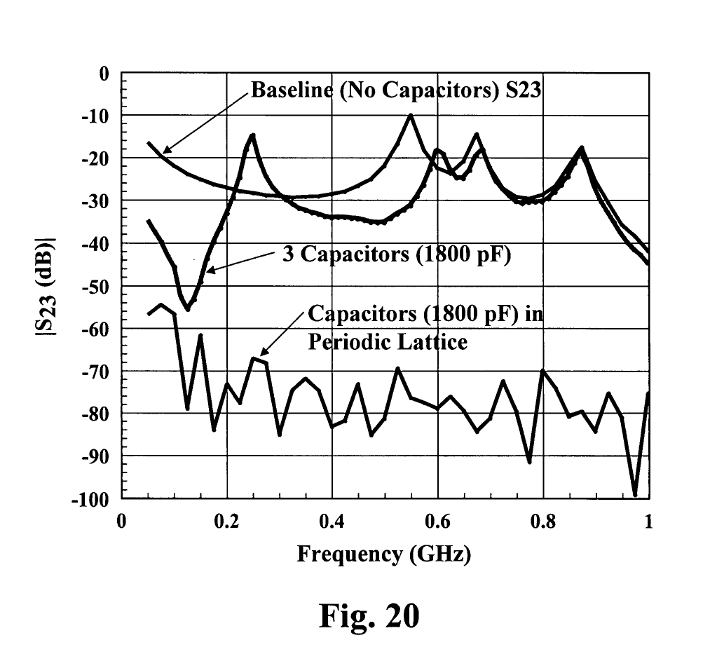

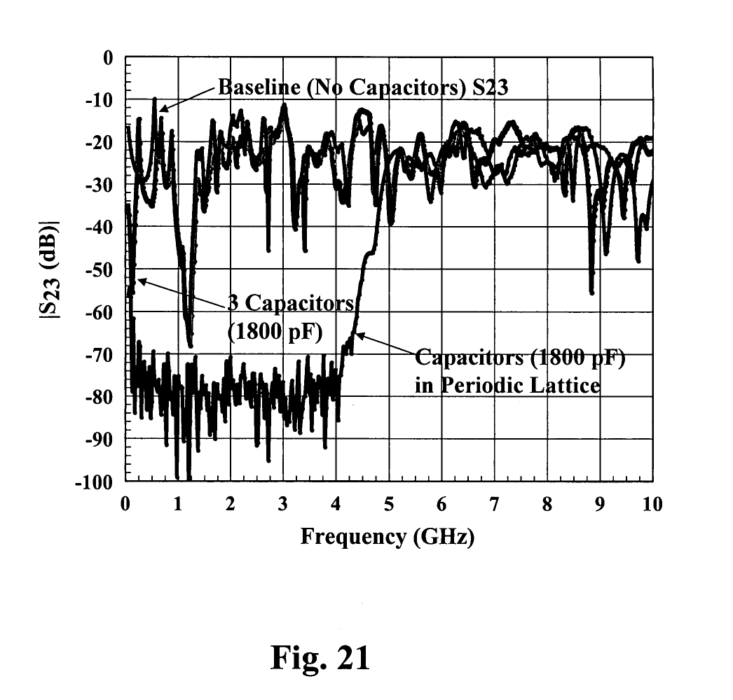

In FIGS. 20 and 21, the coupling for the baseline PPW may be compared to embodiments of parallel plate waveguides loaded with SMT capacitors only and without buried patches. The same data is plotted in both figures. However, in FIG. 20 the frequency range is 0 to 1 GHz, and in FIG. 21 the frequency range is 0 to 10 GHz. FIG. 20 shows that three isolated 1800 pF capacitors have a self resonant frequency of 125 MHz when connected to the PPW through conducting vias of diameter 40 mils and length 30 mils. These three capacitors alone are not very useful for decoupling high frequency noise from the power planes at frequencies above 200 MHz since the transmission data approaches that of the baseline PPW at this frequency. However, when the same 1800 pF capacitors are placed in a lattice structure throughout the PCB, significant decoupling occurs up to a maximum frequency of 4 GHz as seen in FIG. 20. Thus, the use of SMT capacitors even without buried patches has extended the upper frequency limit of the stopband of isolated capacitors from several hundred MHz to 4 GHz in this example. The stopband of 50 MHz to 4 GHz in this case covers the low frequency spectrum not addressed by the structures available in reference [1].

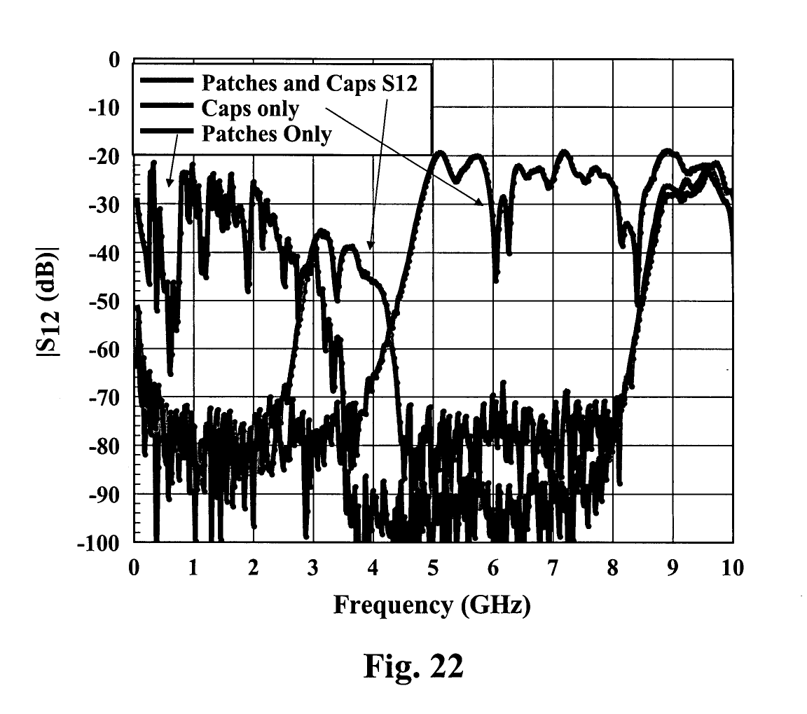

In FIG. 22 the coupling measurements between the first and second ports (S12) for three configurations are compared: SMT capacitors only, patches only, and SMT capacitors and patches. The array of SMT capacitors alone provide the stopband below 4 GHz and the array of patches alone provide the stopband over 3.5-8.5 GHz. The array of SMT capacitors in conjunction with buried patches results in a passband between 2.5 and 4.5 GHz over which the coupling is attenuated significantly less than in the adjacent stopbands. The existence of this passband can be explained by examining the circuit model for the unit cell in FIG. 9. At frequencies above the series resonance frequency of C2 and L2, this branch of the circuit appears inductive. Thus this branch will form a parallel LC resonant circuit with C1 which will appear as an open circuit at the parallel resonant frequency. Within a narrow band around this parallel resonant frequency, the shunt load of C1 in parallel with L2 and C2 will have a high impedance which will allow coupling to occur from one side of the unit cell to the other. Thus, significant noise suppression is not possible at these frequencies using an arrangement that provides a circuit model.

However, using different component values can change this passband region. This is to say that the passband region may possibly be decreased or eliminated by different combinations of changing the capacitance of the chip capacitors, changing the capacitance formed by the patches (through changing the size of the patches or the dielectric constant between the patches and the conductive surface for example), or changing the different inductances (through changing the size, number, and/or distribution of the vias for example).

Of course, in addition to the arrangements of the patches shown in the figures, it is possible to use other arrangements, such as those shown in the patent applications incorporated by reference. Rather than present all of the figures and describe them again, a brief summary of some of the arrangements follows.

Methods of reducing the lower edge of the fundamental stopband for arrays with patches only, one may increase the capacitance of the patches by increasing the dielectric constant of the material between the patches and the conductive surface of the upper layer, increasing the area of the patches, or reducing the thickness between the patches and the conductive surface of the upper layer, increase the height of the PPW, or increase the inductance of the via by decreasing the cross sectional area of the vias. To increase the upper edge of the fundamental stopband one may decrease the period of the array, decrease the effective dielectric constant of the PPW, or increase the inductance of the via by increasing the cross sectional area of the via and/or providing multiple vias for the same patch.

Embodiments may be used that adjust the thicknesses and dielectric constants of the dielectric layers, adjust the height of the overall PCB structure, adjust the shapes and sizes of the patches and/or vias, coplanar spirals or meanderlines may be formed to increase the series inductance (L₁) without increasing the period of the array, or multiple levels of capacitive patches may be used to increase the capacitance. The last embodiment may be readily integratable with existing board designs if even numbers of layers of patches are used. This permits addition of an even number of layers to an existing board design and while still maintaining advantages provided by the use of only even numbers of layers in board designs.

The height of the overall PCB structure may be minimized as in many applications it is desirable to reduce the vertical dimension of a printed circuit board (PCB). Current stack-up dimensions of state-of-the-art computer servers for example may contain five or more pairs of power/ground planes in one PCB. Power system designers attempt to place power and ground planes as close together as possible to obtain the lowest characteristic impedance possible for the power distribution system with typical separation distances of 10 mils or less. Spacing is as close as 2 mils in some cases. This low characteristic impedance minimizes the voltage fluctuations present on a power distribution network (PDN) when transients of supply current are present.

Inhomogeneous mode suppression structures may be created to create broader frequency stopbands between two different reference plane locations on the same PCB. In these structures, the band edges vary in frequency as a function of lateral position within the PCB because the properties of the unit cell change with location. Non-planar structures such as those curved in cross section (including coaxial or square cross sections) and non-uniform patches and/or vias may also be used.

From the foregoing, it can be seen that the present embodiments provide improved circuits, devices and methods for reducing induced power plane noise and improving RF isolation. The devices may be embodied as periodic structures within waveguides capable of supporting TEM mode propagation, or as transverse electromagnetic mode suppression circuits. These embodiments have several distinct advantages over conventional EMI or EMC solutions.

The embodiments offer significantly more RF isolation than is attainable from discrete bypass capacitors or arrays of patches alone. Isolation levels of 70 dB or more are practical between points on a power plane separated by only 2.5 inches. The disclosed embodiments cut off parallel plate modes that travel in any transverse direction, assuming the power plane is large enough in transverse dimensions to accommodate several periods of cells. These embodiments can readily be designed to have a transmission zero (L₁C₁ resonance) as low as 50 MHz or less when SMT capacitors are added to the structure.

It is therefore intended that the foregoing detailed description be regarded as illustrative rather than limiting, and that it be understood that it is the following claims, including all equivalents, that are intended to define the spirit and scope of this invention. For example, the geometries and material properties discussed herein and shown in the embodiments of the figures are intended to be illustrative only. Other variations may be readily substituted and combined to achieve particular design goals or accommodate particular materials or manufacturing processes.

1. An apparatus for suppressing noise in an electrical device, the apparatus comprising:
a first conductive layer;
a second conductive layer separated from the first conductive layer;
first conductive rods connected to the second conductive layer and extending to the first conductive layer; and
chip capacitors connected to the first conductive rods and arranged in a lattice.

2. The apparatus of claim 1 wherein the chip capacitors connect the first conductive rods to the first conductive layer.

3. The apparatus of claim 1 wherein the chip capacitors are arrayed over substantially an entire area of the first conductive layer.

4. The apparatus of claim 1 further comprising a first dielectric layer disposed between the first and second conductive layers and through which the first conductive rods pass.

5. The apparatus of claim 4 further comprising a third conductive layer disposed on an opposite side of the second conductive layer as the first conductive layer and a second dielectric layer disposed between the second and third conductive layers.

6. The apparatus of claim 5 wherein the first conductive rods pass through the second dielectric layer and extend to the third conductive layer, the chip capacitors are arranged in a lattice on the first and third conductive layers and connect the first conductive rods to the first and third conductive layers, respectively.

7. The apparatus of claim 1 wherein the first conductive rods comprise plated vias.

8. The apparatus of claim 7 wherein the first conductive layer houses pads to which the conductive rods and chip capacitors are connected, and a clearance space is disposed between the pads and metal of the first conductive layer.

9. The apparatus of claim 1 further comprising a lattice of conductive coplanar patches disposed between the first and second conductive layers.

10. The apparatus of claim 9 wherein the patches are connected with the second conductive layer and the chip capacitors through the first conductive rods.

11. The apparatus of claim 10 wherein each patch is connected to one of the chip capacitors through one of the first conductive rods.

12. The apparatus of claim 10 further comprising a third dielectric layer disposed between the patches and the second conductive layer and a fourth dielectric layer disposed between the patches and the first conductive layer.

13. The apparatus of claim 10 wherein at least one lattice of the chip capacitors and the patches are arrayed over substantially an entire area of the first conductive layer.

14. The apparatus of claim 13 wherein both the lattice of the chip capacitors and the patches extend over substantially the entire area of the first conductive layer.

15. The apparatus of claim 1 further comprising:
a fourth conductive layer disposed between the first and second conductive layers and which is at a different potential from the second conductive layer; and
second conductive rods connected to the fourth conductive layer and extending to the first conductive layer,
wherein the chip capacitors connect the first conductive rods to the second conductive rods.

16. The apparatus of claim 15 wherein the chip capacitors are arrayed over substantially an entire area of the first conductive layer.

17. The apparatus of claim 15 further comprising a fifth dielectric layer disposed between the second and fourth conductive layers and through which the first conductive rods pass and a sixth dielectric layer disposed between the first and fourth conductive layers and through which the first and second conductive rods pass.

18. The apparatus of claim 17 further comprising a fifth conductive layer disposed on an opposite side of the second conductive layer as the first conductive layer and a seventh dielectric layer disposed between the second and fifth conductive layers.

19. The apparatus of claim 18 wherein the first conductive rods pass through the seventh dielectric layer and extend to the fifth conductive layer, the second conductive rods pass through the fifth and seventh dielectric layers and extend to the fifth conductive layer.

20. The apparatus of claim 19 wherein the chip capacitors are arranged in a lattice only one of the first and fifth conductive layers.

21. The apparatus of claim 19 wherein the chip capacitors are arranged in a lattice on both the first and fifth conductive layers.

22. The apparatus of claim 15 further comprising a lattice of conductive coplanar patches disposed between the first and second conductive layers.

23. The apparatus of claim 22 wherein the patches are closer to the fourth conductive layer than the second conductive layer.

24. The apparatus of claim 22 wherein the patches are connected with the second conductive layer and the chip capacitors through the first conductive rods.

25. The apparatus of claim 24 further comprising an eight dielectric layer disposed between the patches and the second conductive layer and through which the first conductive rods pass, a ninth dielectric layer disposed between the first and fourth conductive layers and through which the first and second conductive rods pass, and a tenth dielectric layer disposed between the patches and the fourth conductive layer.

26. The apparatus of claim 25 wherein at least one lattice of the chip capacitors and the patches are arrayed over substantially an entire area of the first conductive layer.

27. The apparatus of claim 26 wherein both the lattice of the chip capacitors and the patches extend over substantially the entire area of the first conductive layer.

28. The apparatus of claim 25 further comprising a sixth conductive layer disposed on an opposite side of the second conductive layer as the first conductive layer and an eleventh dielectric layer disposed between the second and sixth conductive layers.

29. The apparatus of claim 28 wherein the first conductive rods pass through the eleventh dielectric layer and extend to the sixth conductive layer, the second conductive rods pass through the eight and eleventh dielectric layers and extend to the sixth conductive layer.

30. The apparatus of claim 29 wherein the chip capacitors are arranged in a lattice only one of the first and sixth conductive layers.

31. The apparatus of claim 30 wherein the chip capacitors are arranged in a lattice on both the first and sixth conductive layers.

32. A printed circuit board (PCB) comprising:
a power distribution network including a periodic structure integral with a parallel-plate waveguide operative to define a fundamental stopband over a range of frequencies, the periodic structure including:
a first conductive layer,
a second conductive layer,
an array of conductive coplanar patches more proximate to the first conductive layer than the second conductive layer,
dielectric layers separating the layers,
conductive rods connected to the second conductive layer and extending through the first conductive layer, and
an array of chip capacitors disposed over substantially the entirety of the first conductive layer, the chip capacitors connecting the conductive rods with metal of the first conductive layer,
wherein at least a capacitance formed by the patches and the first conductive layer, a capacitance of the array of chip capacitors, and inductance of the rods are selected to optimize suppression of noise over the at least one stopband.

33. The PCB of claim 32 wherein a lower edge of the fundamental stopband is less than 100 MHz for a unit cell area of the array of less than about 0.1 square inches.

34. The PCB of claim 32 wherein an average of a maximum attenuation of the PCB in the fundamental stopband from about 100 MHz to 2 GHz is at least about 40 dB for locations separated by at least 7 unit cells compared with a PCB that does not contain the array of patches and the array of chip capacitors.

35. A printed circuit board (PCB) comprising:
a first signal layer disposed on an outer surface of the PCB;
a ground plane;
a power plane;
an array of conductive coplanar patches more proximate to the power plane than the ground plane;
dielectric layers separating the ground and power planes, the signal layer; and the patches;
an array of capacitors disposed on the first signal layer;
first pads disposed on the first signal layer and on which the capacitors are mounted; and
first plated through holes connecting the ground plane and patches with the pads and capacitors.

36. The PCB of claim 35 further comprising second pads disposed on the first signal layer and on which the capacitors are mounted and second plated through holes connecting the power plane with the second pads and capacitors, wherein the first and second pads are separated from each other.

37. The PCB of claim 35 further comprising:
a second signal layer disposed on another outer surface of the PCB;
third pads disposed on the second signal layer; and
third plated through holes connecting the third pads with the ground plane.

38. The PCB of claim 37 further comprising an array of capacitors disposed on the second signal layer and mounted on the third pads.

39. The PCB of claim 35 wherein the capacitors are connected to signal lines on the first signal layer.

40. The PCB of claim 36 further comprising:
a second signal layer disposed on another outer surface of the PCB;
fourth pads disposed on the second signal layer; and
fourth plated through holes connecting the fourth pads with the ground plane.

41. The PCB of claim 40 further comprising an array of capacitors disposed on the second signal layer and mounted on the fourth pads.

42. The PCB of claim 41 further comprising fifth pads disposed on the second signal layer and on which the capacitors are mounted and fifth plated through holes connecting the power plane with the fifth pads and capacitors, wherein the fourth and fifth pads are separated from each other.

43. A method for suppressing noise in a printed circuit board (PCB), the method comprising selecting locations of the PCB between which suppression of the noise is desired, arranging a plurality of unit cells of a lattice of chip capacitors between the locations, and mounting the capacitors on the PCB such that one end of the capacitors are grounded.

44. The method of claim 43 further comprising mounting an opposing end of the capacitors such that the capacitors are connected with a power plane.

45. The method of claim 43 further comprising mounting an opposing end of the capacitors such that the capacitors are connected with signal lines of the PCB.

46. The method of claim 43 further comprising arranging a lattice of buried patches between the locations under the lattice of capacitors.

47. The method of claim 46 further comprising providing substantially the same number of patches and capacitors and arranging the patches such that the patches and capacitors are substantially in one-to-one correspondence with each other.
